(19) United States
(12) Patent Application Publication
(10) Pub. No.: US 2025/0224658 A1
(43) Pub. Date: Jul. 10, 2025

(54) WAVELENGTH CONVERTING APPARATUS, LIGHT SOURCE APPARATUS, AND PROJECTOR

(71) Applicant: SEIKO EPSON CORPORATION, Tokyo (JP)

(72) Inventors: Masato KADOTANI, MATSUMOTO-SHI (JP); Naoya SHINDO, AZUMINO-SHI (JP); Kiyotaka MARUYAMA, MATSUMOTO-SHI (JP)

(21) Appl. No.: 19/014,474

(22) Filed: Jan. 9, 2025

(30) Foreign Application Priority Data
Jan. 9, 2024 (JP) 2024-001128

(51) Int. Cl. G03B 21/16; G03B 21/20; H05K 7/20

(52) U.S. Cl. CPC G03B 21/16; G03B 21/204; H05K 7/20327; H05K 7/20336

(57) ABSTRACT

A wavelength converting apparatus includes a phosphor that is a heat source and is configured to emit light having a specific wavelength band; and a cooling apparatus that includes a planar heat receiver at which the phosphor is disposed, and is configured to dissipate heat of the phosphor received by the heat receiver.

The present application is based on, and claims priority from JP Application Serial Number 2024-001128, filed Jan. 9, 2024, the disclosure of which is hereby incorporated by reference herein in its entirety.

### BACKGROUND

### 1. Technical Field

The present disclosure relates to a wavelength converting apparatus, a light source apparatus, and a projector.

### 2. Related Art

In related art, there is a known projector that modulates light output from a light source apparatus to form image light in accordance with image information, enlarges the formed image light, and projects the enlarged image light toward a screen or any other object (see JP-A-2018-180107, for example).

In the projector described in JP-A-2018-180107, the light source apparatus includes a light source including multiple semiconductor lasers, a half-wave plate, a polarization separator, a fluorescence emitter, a quarter-wave plate, and a diffusive reflector.

The luminous flux output from the light source enters the half-wave plate.

The luminous flux having passed through the half-wave plate is incident on the polarization separator. The polarization separator reflects the s-polarized component of the incident luminous flux and transmits the p-polarized component thereof. The polarization separator transmits light having a wavelength band different from the wavelength band of the luminous flux output from the light source.

The fluorescence emitter includes a substrate that supports a phosphor layer and a reflection layer. The phosphor layer contains phosphor particles that convert the s-polarized component incident from the polarization separator into yellow fluorescence, and output the yellow fluorescence. The substrate of the fluorescence emitter is thermally coupled to a body portion that is a housing part made of metal.

The quarter-wave plate is disposed between the polarization separator and the diffusive reflector.

The diffusive reflector diffusively reflects the circularly polarized luminous flux incident from the polarization separator via the quarter-wave plate.

The luminous flux having the s-polarized component and output from the polarization separator is converted into fluorescence by the fluorescence emitter, and the fluorescence passes through the polarization separator. The luminous: the p-polarized component and output from the polarization separator passes through the quarter-wave plate, which converts the incident luminous flux into circular polarized light, which is then incident on the diffusive reflector. Since the polarization rotation direction of the circularly polarized luminous flux reflected off the diffusive reflector is opposite the polarization rotation direction of the circularly polarized luminous flux incident on the diffusive reflector, the circularly polarized luminous flux reflected off the diffusive reflector is converted by the quarter-wave plate into a luminous flux having the s-polarized component. The converted s-polarized luminous flux having the s-polarized component is then reflected off the polarization separator. The polarization separator combines the luminous flux having the s-polarized component and the fluorescence with each other to generate white illumination light, which is output from the light source apparatus.

JP-A-2018-180107 is an example of the related art.

In the light source apparatus described in JP-A-2018-180107, the phosphor layer is supported by the substrate, and the substrate is thermally coupled to the housing part made of metal. Heat generated in the phosphor layer is therefore transferred to the housing part via the substrate. The aforementioned configuration of the light source apparatus has a problem of insufficient efficiency of heat transfer from the phosphor layer to the housing part due to the presence of the substrate, so that an increase in the amount of light that enters the phosphor layer tends to lower the wavelength conversion efficiency and deterioration of the phosphor layer.

The problem described above leads to a demand for a configuration capable of satisfactorily transferring the heat from the phosphor.

### SUMMARY

A wavelength converting apparatus according to a first aspect of the present disclosure includes: a phosphor that is a heat source and is configured to emit light having a specific wavelength band; and a cooling apparatus that includes a planar heat receiver at which the phosphor is disposed, and is configured to dissipate heat of the phosphor received by the heat receiver.

A light source apparatus according to a second aspect of the present disclosure includes: the wavelength converting apparatus according to the first aspect described above; and a light source configured to output light that enters the phosphor.

A projector according to a third aspect of the present disclosure includes: the light source apparatus according to the second aspect described above; a light modulator configured to modulate light from the light source apparatus; and a projection optical apparatus configured to project the light modulated by the light modulator.

### BRIEF DESCRIPTION OF THE DRAWINGS

FIG. 1 is a diagrammatic view showing the configuration of a projector according to a first embodiment.

FIG. 2 is a cross-sectional view showing the configuration of a light source apparatus according to the first embodiment.

FIG. 3 is a perspective view showing a wavelength converting apparatus according to the first embodiment.

FIG. 4 is a side view showing the wavelength converting apparatus according to the first embodiment.

FIG. 5 is a perspective view showing the wavelength converting s according to the first embodiment.

FIG. 6 is a perspective view showing a wavelength converting apparatus provided in a projector according to a second embodiment.

FIG. 7 is a cross-sectional view showing the wavelength converting apparatus according to the second embodiment.

FIG. 8 is a cross-sectional view showing a wavelength converting apparatus provided in a projector according to a third embodiment.

FIG. 9 is a diagrammatic view showing a wavelength converting apparatus provided in a projector according to a fourth embodiment.

FIG. 10 is a cross-sectional view showing a wavelength converting apparatus provided in a projector according to a fifth embodiment.

### DESCRIPTION OF EMBODIMENTS

### First Embodiment

A first embodiment of the present disclosure will be described below with reference to the drawings.

### Schematic Configuration of Projector

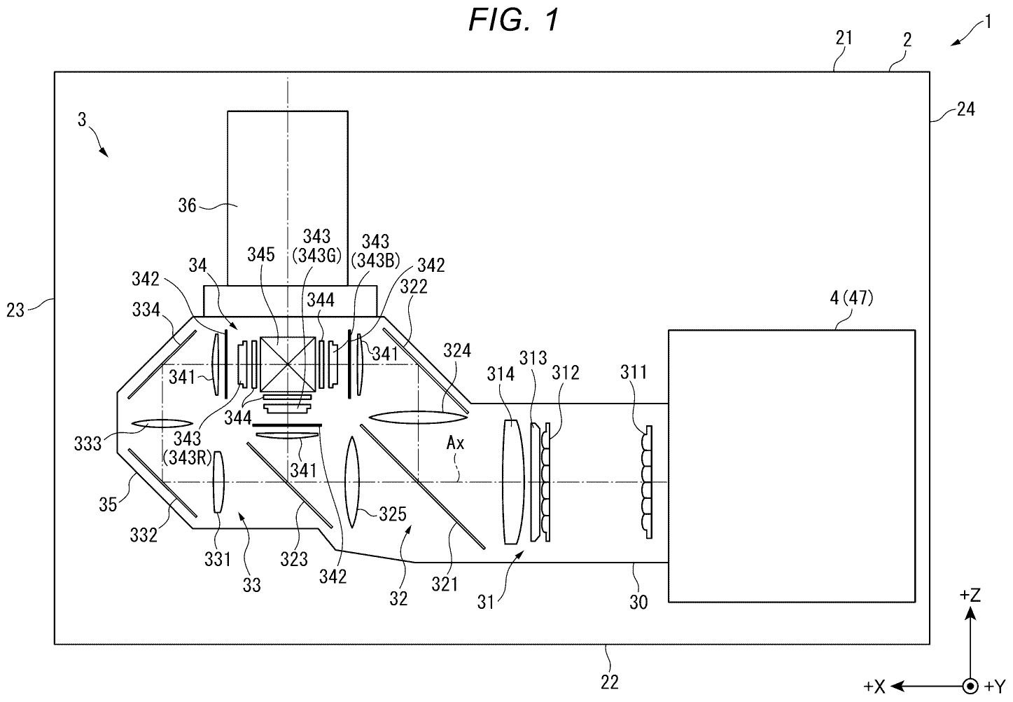

FIG. 1 is a diagrammatic view showing the configuration of a projector 1 according to the present embodiment.

The projector 1 according to the present embodiment projects image light according to image information. The projector 1 includes an exterior enclosure 2 and an image projecting apparatus 3 housed in the exterior enclosure 2, as shown in FIG. 1. In addition, the projector 1 includes, although not shown, a control apparatus that controls the operation of the projector 1, a power supply apparatus that supplies electronic parts of the projector 1 with electric power, and a cooling apparatus that cools cooling targets in the projector 1.

### Configuration of Exterior Enclosure

The exterior enclosure 2 includes a front surface section 21, a rear surface section 22, a left side surface section 23, a right side surface section 24, a top surface section, and a bottom surface section, the latter two of which are not shown, and is formed in a substantially cuboidal shape as a whole.

The front surface section 21 and the rear surface section 22 constitute surfaces of the exterior enclosure 2 that are opposite each other. The front surface section 21 has an opening that exposes a light-exiting-side end portion of a projection optical apparatus 36, which will be described later.

The left side surface section 23 and the right side surface section 24 constitute surfaces of the exterior enclosure 2 that are opposite each other. The top surface section and the bottom surface section constitute surfaces of the exterior enclosure 2 that are opposite each other.

It is assumed in the description below that three directions perpendicular to one another are called +X, +Y, and +Z directions. It is further assumed that the +Z direction is the direction from the rear surface section 22 toward the front surface section 21, that the +X direction is the direction from the right side surface section 24 toward the left side surface section 23, and that the +Y direction is the direction from the bottom surface section toward the top surface section. Although not shown, it is assumed that the opposite direction of the +X direction is a −X direction, that the opposite direction of the +Y direction is a −Y direction, and that the opposite direction of the +Z direction is a −Z direction. It is further assumed that an axis along the +X direction is an X-axis, that an axis along the +Y direction is a Y-axis, and that an axis along the +Z direction is a Z-axis.

### Configuration of Image Projecting Apparatus

The image projecting apparatus 3 forms image light according to input image information and projects the formed image light. The image projecting apparatus 3 includes a light source apparatus 4, an image light generating apparatus 30, and the projection optical apparatus 36.

The light source apparatus 4 outputs illumination light to a homogenizing system 31. The configuration of the light source apparatus 4 will be described later in detail.

The image light generating apparatus 30 generates image light from the illumination light output from the light source apparatus 4. The image light generating apparatus 30 includes the homogenizing system 31, a color separation system 32, a relay system 33, light modulating apparatuses 34, and an optical part enclosure 35.

The homogenizing system 31 homogenizes the illumination light output from the light source apparatus 4. The homogenized illumination light travels via the color separation system 32 and the relay system 33 and illuminates modulation regions of light modulators 343, which will be described later. The homogenizing system 31 includes two lens arrays 311 and 312, a polarization converter 313, and a superimposing lens 314.

The color separation system 32 separates the illumination light incident from the homogenizing system 31 into red light, green light, and blue light. The color separation system 32 includes two dichroic mirrors 321 and 323, a reflection mirror 322, which reflects the blue light separated by the dichroic mirror 321, a lens 324 disposed between the dichroic mirror 321 and the reflection mirror 322, and a lens 325 disposed between the dichroic mirrors 321 and 323.

The relay system 33 is provided in the optical path of the red light, which is longer than the optical paths of the other color light, and suppresses loss of the red light. The relay system 33 includes a light-incident-side lens 331, a relay lens 333, and reflection mirrors 332 and 334. It is assumed in the present embodiment that the red light is guided to the relay system 33, but not necessarily. For example, the blue light may have an optical path longer than those of the other color light and may be guided to the relay system 33.

The light modulating apparatuses 34 modulate the multiple kinds of incident color light, the red light, the green light, and the blue light, and combines the multiple kinds of modulated color light with one another to form the image light. The light modulating apparatuses 34 include three field lenses 341, three light-incident-side polarizers 342, three light modulators 343, and three light-exiting-side polarizers 344, which are all provided in accordance with the multiple kinds of incident color light, and one light combining system 345.

The light modulators 343 modulate the light from the light source apparatus to form the image light. Specifically, the light modulators 343 modulate the multiple kinds of color light incident via the light-incident-side polarizers 342 in accordance with image signals and output the multiple kinds of modulated color light. The three light modulators 343 include a light modulator 343R, which modulates the red light, a light modulator 343G, which modulates the green light, and a light modulator 343B, which modulates the blue light. The light modulators 343 can each, for example, be a transmissive liquid crystal panel.

The light combining system 345 combines the three kinds of color light modulated by the light modulators 343R, 343G, and 343B with one another. The image light as a result of the combination performed by the light combining system 345 enters the projection optical apparatus 36. In the present embodiment, the light combining system 345 is configured with a cross dichroic prism having a substantially cuboidal shape, and may instead be configured with multiple dichroic mirrors.

The optical part enclosure 35 houses the homogenizing system 31, the color separation system 32, and the relay system 33 described above. A designed optical axis Ax is set in the image projecting apparatus 3, and the optical part enclosure 35 holds the homogenizing system 31, the color separation system 32, the relay system 33, and the light modulating apparatuses 34 at predetermined positions on the optical axis Ax. The light source apparatus 4, the light modulating apparatuses 34, and the projection optical apparatus 36 are disposed at predetermined positions on the optical axis Ax.

The projection optical apparatus 36 projects the image light incident from the light modulating apparatuses 34 onto a projection receiving surface such as a screen. That is, the projection optical apparatus 36 projects the image light formed by the light modulating apparatuses 34. The projection optical apparatus 36 can, for example, be a lens assembly including multiple lenses and a lens barrel that houses the multiple lenses.

### Configuration of Light Source Apparatus

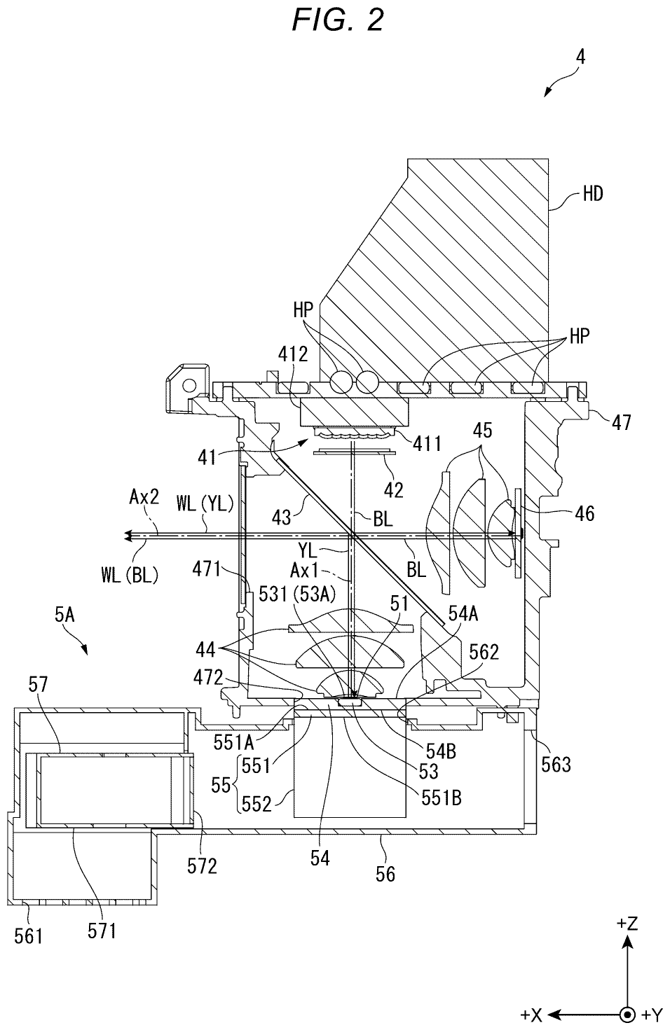

FIG. 2 is a cross-sectional view showing the configuration of the light source apparatus 4. Specifically, FIG. 2 shows a cross section of the light source apparatus 4 taken along the XZ plane.

The light source apparatus 4 outputs illumination light WL in the +X direction toward the homogenizing system 31. The light source apparatus 4 includes a light source 41, a diffusively transmissive section 42, a light separating section 43, a first light collector 44, a wavelength converting apparatus 5A, a second light collector 45, a diffusive optical part 46, and a light source enclosure 47, as shown in FIG. 2.

The following axes are set in the light source apparatus 4: an optical axis Ax1 along the Z-axis; and an optical axis Ax2 along the X-axis, and the optical axes Ax1 and Ax2 are perpendicular to each other. The optical parts of the light source apparatus 4 are disposed in the optical axis Ax1 or Ax2.

Specifically, the light source 41, the diffusively transmissive section 42, the light separating section 43, the first light collector 44, and the wavelength converting apparatus 5A are disposed in the optical axis Ax1.

The diffusive optical part 46, the second light collector 45, and the light separating section 43 are disposed in the optical axis Ax2. That is, the light separating section 43 is disposed at the intersection of the optical axis Ax1 and the optical axis Ax2.

The optical axis Ax2 is linked to the optical axis Ax of the image projecting apparatus 3 at the lens array 311 of the homogenizing system 31.

### Configuration of the Light Source

The light source 41 outputs light in the −Z direction. The light source 41 includes a light emitter 411 and a substrate 412.

The light emitter 411 emits blue light BL. The blue light BL is excitation light that excites phosphor particles contained in a phosphor of the wavelength converting apparatus 5A. The light emitter 411 is, for example, a semiconductor laser that outputs laser light having a peak wavelength of 455 nm.

The substrate 412 is fixed to the inner surface of the light source enclosure 47 while supporting the light emitter 411. The substrate 412 receives heat from the light emitter 411 and transfers the received heat to a heat dissipating part HD exposed to the space outside the light source enclosure 47. Note that the substrate 412 is provided with multiple heat pipes HP. The heat of the light emitter 411 transferred to the substrate 412 is directly transferred from the substrate 412 to the heat dissipating part HD, and is also transferred from the substrate 412 to the heat dissipating part HD via the multiple heat pipes HP.

### Configuration of Diffusively Transmissive Section

The diffusively transmissive section 42 diffuses the blue light BL incident from the light source 41 and outputs light having a homogenized illuminance distribution. The blue light BL output from the diffusively transmissive section 42 is incident on the light separating section 43. The diffusively transmissive section 42 can, for example, have a configuration including a hologram, a configuration in which multiple lenslets are arranged in a plane perpendicular to the optical axis, or a configuration in which light transmitting surfaces are rough surfaces.

In place of the diffusively transmissive section 42, a homogenizer optical element including a pair of multi-lens arrays may be employed in the light source apparatus 4. When the diffusively transmissive section 42 is employed, the distance from the light source 41 to the light separating section 43 can be reduced as compared with the case where the homogenizer optical element is employed.

### Configuration of Light Separating Section

The light separating section 43 has the function of a half-silvered mirror that transmits part of the blue light BL incident from the light source 41 via the diffusively transmissive section 42 and reflects the other part of the blue light BL. That is, the light separating section 43 transmits first partial light that is part of the blue light BL incident from the diffusively transmissive section 42 in the −Z direction to cause the transmitted light to enter the first light collector 44, and reflects second partial light that is the other part of the blue light BL in the −X direction to cause the reflected light to enter the second light collector 45.

The light separating section 43 further has the function of a dichroic mirror that reflects fluorescence YL incident from the wavelength converting apparatus 5A in the +Z direction and transmits the blue light BL incident from the diffusive optical part 46 in the +X direction.

### Configuration of First Light Collector

The first light collector 44 causes the first partial light having passed through the light separating section 43 to be collected at the wavelength converting apparatus 5A. The first light collector 44 parallelizes the fluorescence YL incident from the wavelength converting apparatus 5A and causes the parallelized fluorescence YL to be incident on the light separating section 43 along the +Z direction.

### Schematic Configuration of the Wavelength Converting Apparatus

The wavelength converting apparatus 5A is a reflective wavelength converter that converts the wavelength of the incident light, diffuses the converted light in the opposite direction of the direction of the incident light, and outputs the diffused light. The light output from the wavelength converting apparatus 5A is the fluorescence YL, which is non-polarized light and has peak wavelengths ranging, for example, from 500 to 700 nm, and the fluorescence YL contains green light and red light. The configuration of the wavelength converting apparatus 5A will be described later in detail.

The fluorescence YL output from the wavelength converting apparatus 5A passes through the first light collector 44 along the optical axis Ax1 and is incident on the light separating section 43. The fluorescence YL incident on the light separating section 43 is reflected off the light separating section 43 in the +X direction, and exits out of the light source apparatus 4 along the optical axis Ax2.

### Configuration of Second Light Collector

The second light collector 45 causes the second partial light incident from the light separating section 43 to be collected at the diffusive optical part 46. The second light collector 45 parallelizes the blue light incident from the diffusive optical part 46 and causes the parallelized blue light to be incident on the light separating section 43 along the +Z direction.

### Configuration of Diffusive Optical Part

The diffusive optical part 46 reflects and diffuses the blue light BL incident from the second light collector 45 at diffusion angles substantially equal to the diffusion angles of the fluorescence YL output from the wavelength converting apparatus 5A or diffusion angles slightly smaller than the diffusion angles of the fluorescence YL. That is, the diffusive optical part 46 reflects and diffuses the incident light without converting the wavelength of the incident light.

The blue light BL reflected off the diffusive optical part 46 in the +X direction passes through the second light collector 45, then passes through the light separating section 43 in the +X direction, and exits out of the light source apparatus 4 along with the fluorescence YL.

As described above, the illumination light WL that exits out of the light source apparatus 4 is white light that is the mixture of the blue light BL and the fluorescence YL containing green light and red light. The illumination light WL is output from the light source apparatus 4 in the +X direction via a passage port 471 of the light source enclosure 47.

### Configuration of Light Source Enclosure

The light source enclosure 47 is an enclosure of the light source apparatus 4, and is one of internal enclosures housed in the exterior enclosure 2. The light source enclosure 47 houses the light source 41, the diffusively transmissive section 42, the light separating section 43, the first light collector 44, a phosphor 51 of the wavelength converting apparatus 5A, the second light collector 45, and the diffusive optical part 46. In the present embodiment, the light source enclosure 47 is a sealed enclosure that dirt and dust is unlikely to enter, but not necessarily. The light source enclosure 47 only needs to house the optical parts described above.

The light source enclosure 47 has the passage port 471 and an opening 472.

The passage port 471 is an opening via which the illumination light WL exits out of the light source enclosure 47.

A support part 54, which will be described later and supports the wavelength converting apparatus 5A, is disposed in the opening 472. In detail, the support part 54 is fitted into the opening 472, and a sealing part that is not shown is provided between the inner edge of the opening 472 and the circumferential edge of the support part 54. The light source enclosure 47 is thus maintained hermetically sealed.

### Detailed Configuration of Wavelength Converting Apparatus

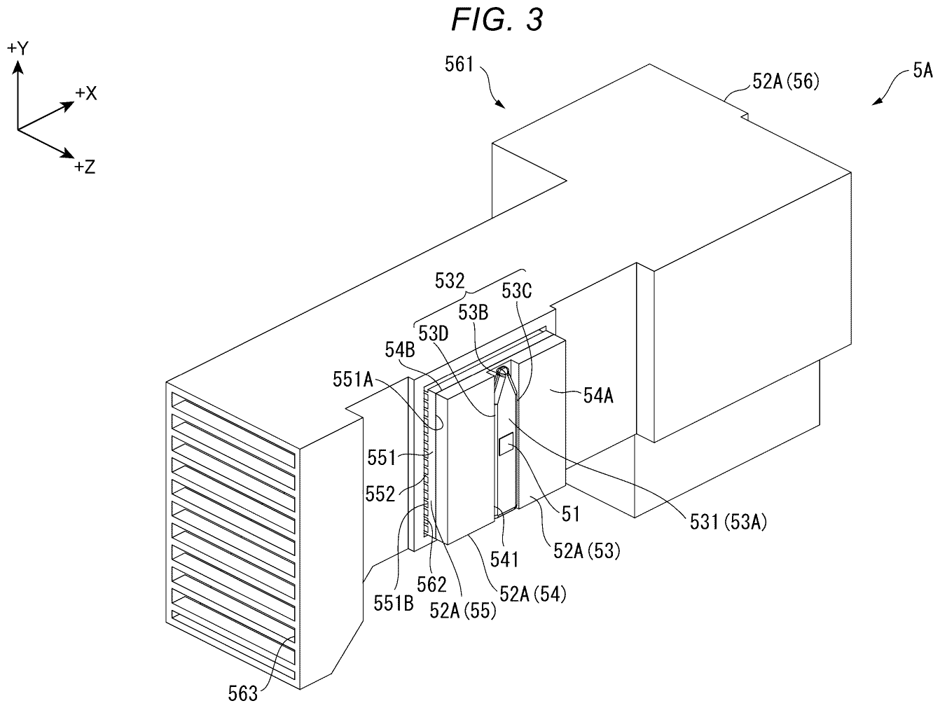

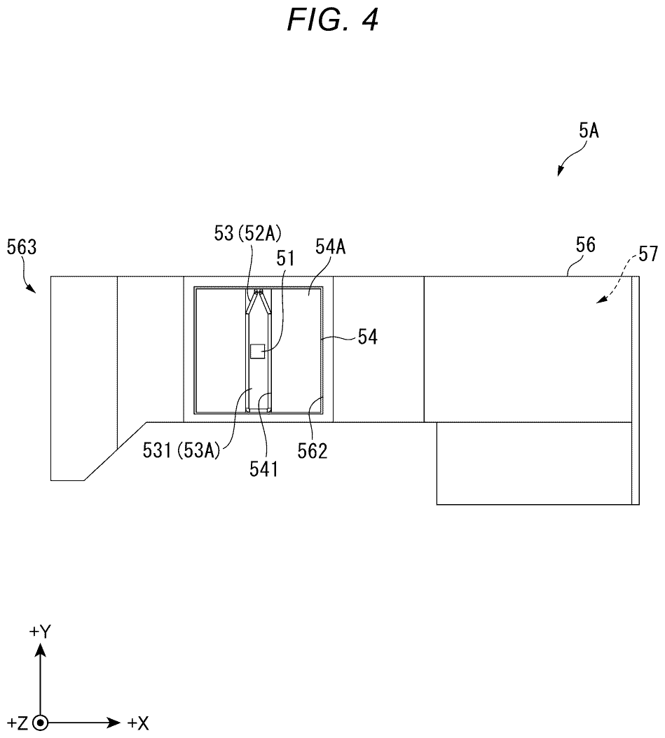

FIG. 3 is a perspective view showing the wavelength converting apparatus 5A viewed from the side facing the side on which the excitation light is incident. FIG. 4 is a side view showing the wavelength converting apparatus 5A viewed from the side facing the side on which the excitation light is incident.

The wavelength converting apparatus 5A outputs the fluorescence YL as a result of the conversion of the wavelength of the incident blue light BL in the opposite direction of the direction in which the blue light BL is incident, as described above. The wavelength converting apparatus 5A includes the phosphor 51 and a cooling apparatus 52A, as shown in FIGS. 3 and 4.

### Configuration of Phosphor

The phosphor 51 emits light having a specific wavelength band. The phosphor 51 is excited with the incident blue light BL, which is the excitation light, and emits the fluorescence YL, as described above. The phosphor 51 includes, for example, a phosphor ceramic material that is a ceramic material containing phosphor particles, and a reflection layer formed at the surface of the phosphor ceramic material that is opposite the side on which the excitation light is incident.

The phosphor 51 is disposed at a position where the blue light BL is collected by the first light collector 44. The phosphor 51 is a heat source and is therefore a cooling target. The phosphor 51 is provided at a heat receiver 531 of the cooling apparatus 52A.

Note that the phosphor 51 is a heat source that generates heat when the excitation light enters the phosphor 51.

### Configuration of Cooling Apparatus

The cooling apparatus 52A supports the phosphor 51. The cooling apparatus 52A receives the heat from the phosphor 51, and dissipates the received heat out of the light source enclosure 47 to cool the phosphor 51. The cooling apparatus 52A includes a heat transporting part 53, the support part 54, a heat dissipating part 55, a duct 56, and a fan 57.

### Configuration of Heat Transporting Part

The heat transporting part 53 is disposed along the Y-axis at the support part 54 while supporting the phosphor 51. The heat transporting part 53 transports the heat received from the phosphor 51 to the heat dissipating part 55 via the support part 54. The heat transporting part 53 includes the heat receiver 531 and a heat dissipater 532. In the present embodiment, the heat transporting part 53 is a heat pipe in which a working fluid is encapsulated. That is, the heat transporting part 53 evaporates the working fluid in the liquid phase by using the heat received by the heat receiver 531 to change the working fluid in the liquid phase to the working fluid in the gaseous phase, and dissipates the heat of the working fluid in the gaseous phase via the heat dissipater 532 to change the working fluid in the gaseous phase to the working fluid in the liquid phase.

The heat receiver 531 constitutes a planar first surface 53A of the heat transporting part 53, which faces the positive end of the Z direction. That is, the heat receiver 531 is formed in a planar shape. The phosphor 51 is fixed to the heat receiver 531 through either solder-based metal joining or metal-based firing fixation, and the heat receiver 531 receives the heat from the phosphor 51. The cooling apparatus 52A includes the heat receiver 531, which receives the heat from the phosphor 51, as described above.

The heat dissipater 532 of the heat transporting part 53 includes a second surface 53B, which is a planar surface facing the negative end of the Z direction, a third surface 53C, which is a convex curved surface facing the positive end of the X direction, and a fourth surface 53D, which is a convex curved surface facing the negative end of the X direction. The second surface 53B is a surface of the heat transporting part 53 that is opposite the first surface 53A. The heat dissipater 532 dissipates the heat of the phosphor 51 to the heat dissipating part 55 via the support part 54.

### Configuration of Support Part

The support part 54 is disposed in the opening 472 of the light source enclosure 47 while supporting the phosphor 51. The support part 54 is coupled to the heat dissipating part 55 in a heat transferable manner, and transmits the heat of the phosphor 51 transferred from the heat transporting part 53 to the heat dissipating part 55. The support part 54 has a first surface 54A facing the positive end of the Z direction, and a second surface 54B facing the negative end of the Z direction, and the first surface 54A and the second surface 54B are surfaces of the support part 54 that are opposite each other.

The first surface 54A is provided with a groove 541 recessed in the −Z direction and extending along the Y-axis. The heat transporting part 53 is disposed in the groove 541. The heat dissipater 532 of the heat transporting part 53 is thermally coupled to the inner surface of the groove 541. That is, the heat of the phosphor 51 dissipated from the heat transporting part 53 is transferred to the inner surface of the groove 541.

The second surface 54B is a substantially planar surface to which a base 551 of the heat dissipating part 55 is coupled. The second surface 54B is exposed to the space outside the light source enclosure 47 when the support part 54 is fitted into the opening 472 described above.

The support part 54 is, for example, a part made of metal, such as aluminum or copper, and transfers the heat of the phosphor 51 transferred to the groove 541 in the first surface 54A to the base 551 of the heat dissipating part 55 coupled to the second surface 54B.

### Configuration of Heat Dissipating Part

The heat dissipating part 55 is fixed to the second surface 54B exposed to the space outside the light source enclosure 47, and is disposed in the duct 56 combined with the light source enclosure 47. The heat dissipating part 55 is a heat sink including the base 551 and multiple fins 552 extending from the base 551.

The base 551 is formed in the shape of a planar plate having a first surface 551A facing the positive end of the Z direction and a second surface 551B facing the negative end of the Z direction. The first surface 551A and the second surface 551B are surfaces of the base 551 that are opposite each other, and the first surface 551A is coupled to the second surface 54B.

The multiple fins 552 each extend in the −Z direction from the second surface 551B of the base 551, and are arranged side by side along the Y-axis. The heat of the phosphor 51 transferred from the support part 54 to the base 551 is transferred to the multiple fins 552. At least portions of the multiple fins 552 are disposed in the duct 56, and the multiple fins 552 transfer the heat of the phosphor 51 to a cooling gas flowing through the duct 56. The heat dissipating part 55 is thus cooled, and in turn the phosphor 51 is cooled.

### Configuration of Duct

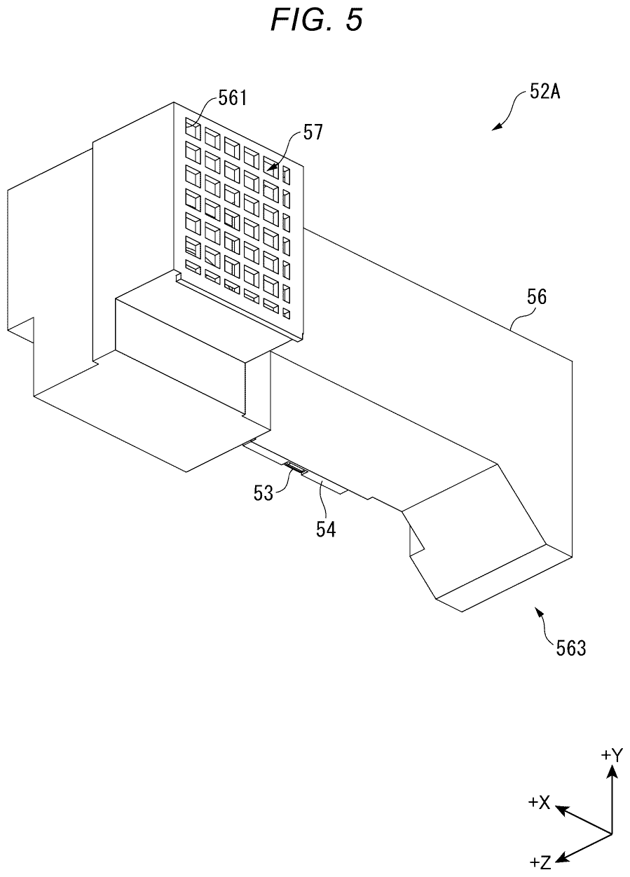

FIG. 5 is a perspective view showing the wavelength converting apparatus 5A viewed from the side opposite the side on which the excitation light is incident.

The duct 56 is configured to allow the cooling gas to flow therethrough, and houses a portion of the heat dissipating part 55 and the fan 57 therein. That is, the duct 56 causes the cooling gas sent from the fan 57 to flow to the heat dissipating part 55 disposed in the duct 56 and discharges the cooling gas out of the duct 56. The duct 56 has introduction ports 561 shown in FIGS. 2 and 5, and an opening 562 and a discharge port 563 shown in FIGS. 2 to 4.

The introduction ports 561 are provided at a portion of the duct 56 and arranged in the +X direction and the −Y direction, and open in the −Z direction, as shown in FIGS. 2 and 5. The introduction ports 561 introduce the gas outside the duct 56 as the cooling gas into the duct 56.

The opening 562 is provided through the surface of the duct 56 that faces the positive end of the Z direction substantially at the center of the surface in the X-axis, as shown in FIGS. 3 and 4. The opening 562 is a rectangular opening when viewed in the +Z direction, and a portion of the heat dissipating part 55 that faces the negative end of the Z direction is inserted into the opening 562 from the side facing the positive end of the Z direction. Portions of the multiple fins 552 that face the negative end of the Z direction are thus disposed in the duct 56.

The discharge port 563 is provided through the surface of the duct 56 that faces the negative end of the X direction, and opens in the −X direction, as shown in FIGS. 2 and 3. The cooling gas sent from the fan 57 in the −X direction and flowing to the heat dissipating part 55 is discharged outside the duct 56 via the discharge port 563.

### Configuration of Fan

The fan 57 is disposed in a space of the duct 56 that faces the positive end of the X direction, and causes the cooling gas to flow through the duct 56. The fan 57 is a centrifugal fan such as a sirocco fan, and is so disposed that an intake surface 571 faces the negative end of the Z direction and an ejection surface 572 faces the negative end of the X direction.

The fan 57 suctions the gas outside the duct 56 via the introduction ports 561, and sends the suctioned cooling gas to the heat dissipating part 55 located away from the fan 57 in the −X direction.

The cooling gas sent to the heat dissipating part 55 flows through the gaps between the multiple fins 552 arranged along the X-axis and receives the heat from the multiple fins 552. The multiple fins 552 are thus cooled, and in turn the phosphor 51 is cooled.

The cooling gas having received the heat from the multiple fins 552 further flows in the −X direction and is discharged out of the duct 56 via the discharge port 563.

### Advantages of First Embodiment

The projector 1 according to the present embodiment described above provides the advantages below.

The projector 1 includes the light source apparatus 4, the light modulators 343, and the projection optical apparatus 36.

The light modulators 343 modulate the light from the light source apparatus 4.

The projection optical apparatus 36 projects the light modulated by the light modulators 343.

The light source apparatus 4 includes the wavelength converting apparatus 5A, and the light source 41, which outputs the light that enters the phosphor 51 of the wavelength converting apparatus 5A.

The wavelength converting apparatus 5A includes the phosphor 51 and the cooling apparatus 52A.

The phosphor 51 is a heat source and emits light having a specific wavelength band.

The cooling apparatus 52A includes the planar heat receiver 531, at which the phosphor 51 is disposed, and dissipates the heat of the phosphor 51 received by the heat receiver 531.

According to the configuration described above, the cooling apparatus 52A can receive the heat generated by the phosphor 51 via the heat receiver 531 and dissipate the received heat to cool the phosphor 51. In the thus configured cooling apparatus 52A, the heat receiver 531 is formed in a planar shape, so that the area where the heat receiver 531 and the phosphor 51 are in contact with each other can be increased, and the phosphor 51 is disposed at the heat receiver 531, so that the heat can be efficiently transferred from the phosphor 51 to the heat receiver 531. The phosphor 51 can therefore be effectively cooled.

According to the thus configured wavelength converting apparatus 5A, the amount of light that enters the wavelength converting apparatus 5A can be increased, so that the light source apparatus 4 can output high-luminescence light, and the projector 1 can project high-luminescence image light.

In the wavelength converting apparatus 5A, the cooling apparatus 52A includes the heat transporting part 53 and the heat dissipating part 55. The heat dissipating part 55 dissipates the transferred heat. The heat transporting part 53 evaporates the working fluid in the liquid phase by using the heat received by the heat receiver 531 to change the working fluid in the liquid phase to the working fluid in the gaseous phase, and dissipates the heat of the working fluid in the gaseous phase to the heat dissipating part 55 via the support part 54 to change the working fluid in the gaseous phase to the working fluid in the liquid phase. The heat receiver 531 is provided as a portion of the heat transporting part 53.

According to the configuration described above, the working fluid having changed from the liquid phase to the gaseous phase by the heat received by the heat receiver 531 changes from the gaseous phase to the liquid phase by transferring the heat to the heat dissipating part 55. The heat received by the heat receiver 531 can thus be quickly transferred to the heat dissipating part 55 via the working fluid. Since the heat of the phosphor 51 can therefore be quickly transferred to the heat dissipating part 55, the efficiency at which the phosphor 51 is cooled can be increased.

The wavelength converting apparatus 5A further includes the support part 54 having the groove 541, in which the heat transporting part 53 is disposed. The heat transporting part 53 is a heat pipe.

According to the configuration described above, the heat transporting part 53, which is a heat pipe, is disposed in the groove 541 of the support part 54, so that the heat transporting part 53 can be disposed in a stable manner.

In the wavelength converting apparatus 5A, the support part 54 receives the heat from the heat transporting part 53, and the heat dissipating part 55 is coupled to the support part 54.

According to the configuration described above, the heat can be transferred from the heat transporting part 53 disposed in the groove 541 to the support part 54, so that the support part 54 can be used as another heat dissipating part. Furthermore, since the heat dissipating part 55 and the support part 54 are coupled to each other, the heat transferred to the support part 54 can be transferred to the heat dissipating part 55. The number of heat transporting paths from the phosphor 51 to the heat dissipating part 55 can therefore be increased, so that the efficiency the heat is transferred from the phosphor 51 to the heat dissipating part 55 can be increased, and the efficiency at which the phosphor 51 is cooled can hence be increased.

The wavelength converting apparatus 5A includes the duct 56 and the fan 57. The heat dissipating part 55 is disposed in the duct 56. The cooling gas can flow through the duct 56. The fan 57 causes the cooling gas to flow through the duct 56.

According to the configuration described above, since the heat dissipating part 55 is disposed in the duct 56, through which the cooling gas is caused to flow by the fan 57, the heat dissipating part 55, to which the heat of the phosphor 51 is transferred, can be effectively cooled, and the efficiency at which the phosphor 51 is cooled can hence be increased.

In the wavelength converting apparatus 5A, the phosphor 51 is fixed to the heat receiver 531 through either solder-based metal joining or metal-based firing fixation.

According to the configuration described above, the thermal resistance between the phosphor 51 and the heat receiver 531 can be reduced, so that the heat can be satisfactorily transferred from the phosphor 51 to the heat receiver 531. The efficiency at which the phosphor 51 is cooled can therefore be increased.

### Second Embodiment

A second embodiment of the present disclosure will next be described.

A projector according to the present embodiment is configured in the same manner as the projector 1 according to the first embodiment, but differs therefrom in the configuration of the heat transporting part and the arrangement of the heat dissipating part. In the following description, portions that are the same or substantially the same as the portions having been already described have the same reference characters and will not be described.

### Schematic Configurations of Projector and Light Source Apparatus

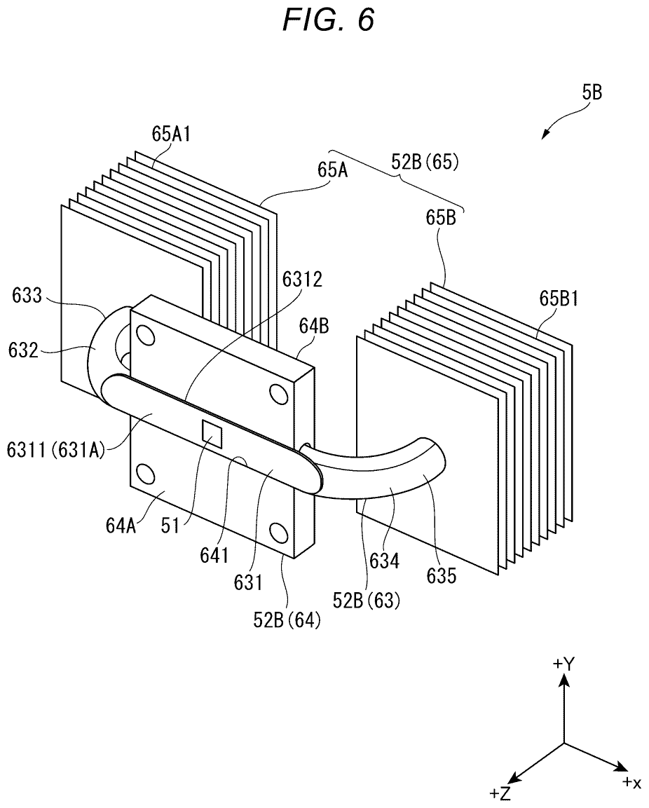

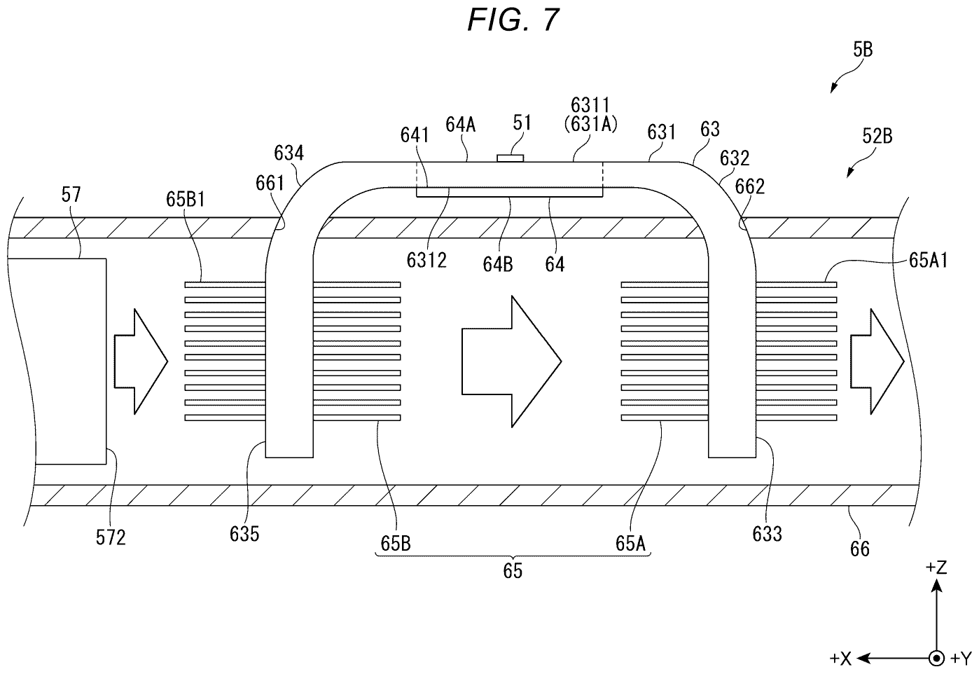

FIG. 6 is a perspective view showing a wavelength converting apparatus 5B provided in the projector according to the present embodiment, and FIG. 7 is a cross-sectional view of the wavelength converting apparatus 5B viewed in the +Y direction. In FIG. 6, note that neither the duct 56 nor the fan 57 is shown.

The projector according to the present embodiment has same configurations and functions as the projector 1 according to the first embodiment except that the wavelength converting apparatus 5A is replaced with the wavelength converting apparatus 5B shown in FIGS. 6 and 7. That is, the light source apparatus 4 according to the present embodiment includes wavelength converting apparatus 5B in place of the wavelength converting apparatus 5A.

### Configuration of Wavelength Converting Apparatus

The wavelength converting apparatus 5B outputs the fluorescence YL as a result of the conversion of the wavelength of the incident blue light BL in the opposite direction of the direction in which the blue light BL is incident, as the wavelength converting apparatus 5A according to the first embodiment. The wavelength converting apparatus 5B has the same configurations and functions as the wavelength converting apparatus 5A except that the cooling apparatus 52A is replaced with a cooling apparatus 52B. That is, the wavelength converting apparatus 5B includes the phosphor 51 and the cooling apparatus 52B.

### Configuration of Cooling Apparatus

The cooling apparatus 52B supports the phosphor 51 and cools the phosphor 51, as the cooling apparatus 52A according to the first embodiment. The cooling apparatus 52B includes a heat transporting part 63, a support part 64, a heat dissipating part 65, a duct 66, and the fan 57.

### Configuration of Heat Transporting Part

The heat transporting part 63 supports the phosphor 51, and transfers the heat received from the phosphor 51 to the support part 64 and the heat dissipating part 65, as the heat transporting part 53. In the present embodiment, the heat transporting part 63 is a heat pipe formed in a substantially U shape, and a working fluid is encapsulated therein. The heat transporting part 63 includes a first extending section 631 along the X-axis, a first curved section 632, a second extending section 633, a second curved section 634, and a third extending section 635.

The first extending section 631 is a portion extending along the X-axis, and is provided at the center of the heat transporting part 63 in the X-axis. The first extending section 631 includes a heat receiver 6311 and a heat dissipater 6312.

The heat receiver 6311 constitutes a planar first surface 631A of the first extending section 631, which faces the positive end of the Z direction. That is, the heat receiver 6311 is formed in a planar shape. The phosphor 51 is fixed to the heat receiver 6311 through either solder-based metal joining or metal-based firing fixation, and the heat receiver 6311 receives the heat from the phosphor 51. The cooling apparatus 52B includes the heat receiver 6311, which receives the heat from the phosphor 51, as described above.

The heat dissipater 6312 is an outer circumferential surface of the first extending section 631 that is a surface facing a groove 641 provided in the support part 64 when the first extending section 631 is disposed in the groove 641. The heat dissipater 6312 dissipates part of the heat of the phosphor 51 received by the heat receiver 6311 to the support part 64.

The first curved section 632 is provided at the end of the first extending section 631 in the −X direction, and is curved so as to extend in the −Z direction as extending in the −X direction.

The second extending section 633 extends linearly in the −Z direction from the end of the first curved section 632 in the −Z direction. The second extending section 633 is provided with a first heat dissipating part 65A of the heat dissipating part 65 in a heat transferable manner. The second extending section 633 is a heat dissipater that dissipates another part of the heat of the phosphor 51 received by the heat receiver 6311 to the first heat dissipating part 65A.

The second curved section 634 is provided at the end of the first extending section 631 in the +X direction, and is curved so as to extend in the −Z direction as extending in the +X direction.

The third extending section 635 extends linearly in the −Z direction from the end of the second curved section 634 in the −Z direction. The third extending section 635 is provided with a second heat dissipating part 65B of the heat dissipating part 65 in a heat transferable manner. The third extending section 635 is a heat dissipater that dissipates another part of the heat of the phosphor 51 received by the heat receiver 6311 to the second heat dissipating part 65B.

### Configuration of Support Part

The support part 64 is disposed in the opening 472 of the light source enclosure 47 while supporting the heat transporting part 63 to which the phosphor 51 is fixed. The support part 64 has a first surface 64A facing the positive end of the Z direction, and a second surface 64B facing the negative end of the Z direction, as the support part 54.

The groove 641 recessed in the −Z direction and extending along the X-axis is formed in the first surface 64A. That is, the support part 64 has the groove 641. The first extending section 631 of the heat transporting part 63 is disposed in the groove 641.

The second surface 64B is the surface of the support part 64 that is opposite the first surface 64A. In the present embodiment, a gap is created between the second surface 64B and the duct 66. That is, the support part 64 is disposed away from the duct 66, but not necessarily. The support part 64 may be coupled to the duct 66, for example, with the second surface 64B being in contact with the surface of the duct 66 that faces the positive end of the Z direction.

### Configuration of Heat Dissipating Part

The heat dissipating part 65 dissipates the heat of the phosphor 51 transferred by the heat transporting part 63. In detail, the heat dissipating part 65 is disposed in the duct 66, and dissipates the transferred heat of the phosphor 51 to the cooling gas flowing from the fan 57. The heat dissipating part 65 includes the first heat dissipating part 65A and the second heat dissipating part 65B provided at opposite ends of the heat transporting part 63.

The first heat dissipation part 65A is attached to the second extending section 633 of the heat transporting part 63 in a heat transferable manner. The first heat dissipating part 65A has multiple fins 65A1.

The second heat dissipating part 65B is attached to the third extending section 635 of the heat transporting part 63 in a heat transferable manner. The second heat dissipating part 65B includes multiple fins 65B1.

The multiple fins 65A1 are each perpendicular to the −Z direction, which is the direction in which the second extending section 633 extends. The multiple fins 65B1 are each perpendicular to the −Z direction, which is the direction in which the third extending section 635 extends. That is, the cooling gas sent from the fan 57 in the −X direction can flow through the gaps between the multiple fins 65A1 and between the multiple fins 65B1.

### Configuration of Duct

The duct 66 guides the cooling gas sent from the fan 57 disposed therein to the heat dissipating part 65, and discharges the cooling gas to which the heat has been transferred by the heat dissipating part 65, as the duct 56. The duct 66 has the introduction ports 561 and the discharge port 563, neither of which is shown in FIG. 7, as the duct 56, and further has insertion ports 661 and 662 shown in FIG. 7.

The insertion ports 661 and 662 are provided in the surface of the duct 66 that faces the positive end of the Z direction. The first curved section 632 of the heat transporting part 63 is inserted into the insertion port 661. The second curved section 634 of the heat transporting part 63 is inserted into the insertion port 662. The heat transporting part 63 is thus so disposed that the first extending section 631, to which the phosphor 51 is fixed, is disposed outside the duct 66, and the second extending section 633, to which the first heat dissipating part 65A is attached, and the third extending section 635, to which the second heat dissipating part 65B is attached, are disposed in the duct 66.

### Dissipation of Heat of Phosphor

Part of the heat of the phosphor 51 received by the heat receiver 6311 of the heat transporting part 63 is transferred to the support part 64, the other part of the heat is transferred by the working fluid in the heat transporting part 63 to the second extending section 633 and the third extending section 635, so that the heat is transferred to the heat dissipating parts 65A and 65B.

The cooling gas sent in the −X direction from the fan 57 flows through the gaps between the multiple fins 65A1 of the first heat dissipating part 65A and between the multiple fins 65B1 of the second heat dissipating part 65B, so that the heat dissipating parts 65A and 65B are cooled, and in turn the phosphor 51 is cooled. The cooling gas having cooled the fins 65A1 and 65B1 is discharged in the −X direction via the discharge port 563, which is not shown, of the duct 66.

### Advantages of Second Embodiment

The projector according to the present embodiment described above provides the following advantages as well as the same advantages provided by the projector 1 according to the first embodiment.

In the wavelength converting apparatus 5B, the heat dissipating part 65 is provided at each of the opposite ends of the heat transporting part 63, which is a heat pipe. Specifically, the heat dissipating part 65 includes the first heat dissipating part 65A and the second heat dissipating part 65B, with the first heat dissipating part 65A provided at the end of the heat transporting part 63 in the −X direction, the second heat dissipating part 65B provided at the end of the heat transporting part 63 in the +X direction.

The configuration described above allows an increase in the area via which the heat of the phosphor 51 is dissipated. Furthermore, the distance between the heat receiver 6311 and the heat dissipating part 65 can be shortened as compared with the case where the heat receiver is provided at one end of the heat pipe and the heat dissipating part is provided at the other end of the heat pipe, so that the heat of the phosphor 51 can be transferred to the heat dissipating part 65 quickly and efficiently. The efficiency at which the phosphor 51 is cooled can therefore be increased.

### Third Embodiment

A third embodiment of the present disclosure will next be described.

A projector according to the present embodiment is configured in the same manner as the projector 1 according to the first embodiment, but differs therefrom in the heat transporting part and the support part, which constitute the wavelength converting apparatus. In the following description, portions that are the same or substantially the same as the portions having been already described have the same reference characters and will not be described.

### Schematic Configurations of Projector and Light Source Apparatus

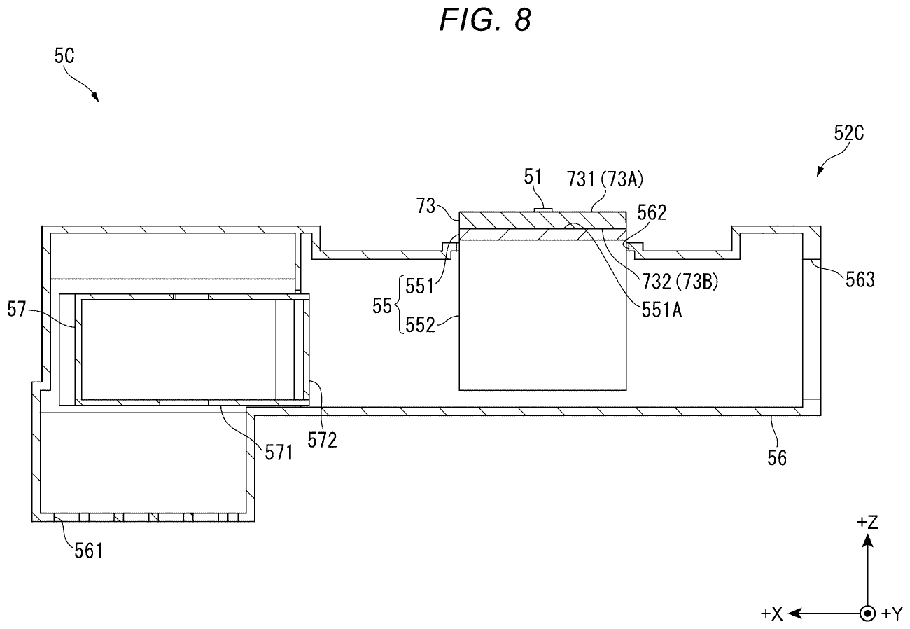

FIG. 8 is a cross-sectional view of a wavelength converting apparatus 5C provided in the projector according to the present embodiment and viewed in the +Y direction.

The projector according to the present embodiment has same configurations and functions as the projector 1 according to the first embodiment except that the wavelength converting apparatus 5A is replaced with the wavelength converting apparatus 5C shown in FIG. 8. That is, the light source apparatus 4 according to the present embodiment includes the wavelength converting apparatus 5C in place of the wavelength converting apparatus 5A.

### Configuration of Wavelength Converting Apparatus

The wavelength converting apparatus 5C outputs the fluorescence YL as a result of the conversion of the wavelength of the incident blue light BL in the opposite direction of the direction in which the blue light BL is incident, as the wavelength converting apparatuses 5A and 5B according to the first and second embodiments. The wavelength converting apparatus 5C has the same configurations and functions as the wavelength converting apparatus 5A except that the cooling apparatus 52A is replaced with a cooling apparatus 52C. That is, the wavelength converting apparatus 5C includes the phosphor 51 and the cooling apparatus 52C.

### Configuration of Cooling Apparatus

The cooling apparatus 52C supports the phosphor 51 and cools the phosphor 51, as the cooling apparatus 52A according to the first embodiment. The cooling apparatus 52C includes a heat transporting part 73, the heat dissipating part 55, the duct 56, and the fan 57. In the cooling apparatus 52C, the support part that supports the heat transporting coupled to the heat dissipating part is omitted, and the heat transporting part 73 and the heat dissipating part 55 are coupled to each other in a heat transferable manner, but not necessarily. The cooling apparatus 52C may include a support part that supports the heat transporting part 73 and the heat dissipating part 55.

### Configuration of Heat Transporting Part

The heat transporting part 73 supports the phosphor 51, and receives the heat from the phosphor 51, as the heat transporting part 53 according to the first embodiment. The heat transporting part 73 is formed in the shape of a substantially planar plate, is disposed in the opening 472 of the light source enclosure 47 in the state in which the heat transporting part 73 supports the phosphor 51, and is fixed in the opening 472.

The heat transporting part 73 has a first surface 73A, which is a planar surface facing the positive end of the Z direction, and a second surface 73B, which is a planar surface facing the negative end of the Z direction, and the first surface 73A and the second surface 73B are surfaces of the heat transporting part 73 that are opposite each other. In addition, the heat transporting part 73 includes a heat receiver 731 and a heat dissipater 732.

The heat receiver 731 is a portion of the first surface 73A to which the phosphor 51 is fixed through either solder-based metal joining or metal-based firing fixation, and is formed in a planar shape. That is, the heat receiver 731 is located at the first surface 73A. The heat receiver 731 receives the heat from the phosphor 51. The cooling apparatus 52C includes the heat receiver 731, which receives the heat from the phosphor 51, as described above.

The heat dissipater 732 constitutes the second surface 73B, and dissipates the heat of the phosphor 51 received by the heat receiver 731 to the first surface 551A of the base 551 of the heat dissipating part 55 coupled to the second surface 73B.

The thus configured heat transporting part 73 can be configured with a vapor chamber in which a working fluid is encapsulated, or can be configured with a Peltier device, which is a thermoelectric conversion device.

### Dissipation of Heat of Phosphor

The heat of the phosphor 51 received by the heat receiver 731 of the heat transporting part 73 is transferred to the heat dissipating part 55 by the heat transporting part 73. The heat of the phosphor 51 transferred to the heat dissipating part 55 is transferred to the multiple fins 552 of the heat dissipating part 55.

The cooling gas sent from the fan 57 in the −X direction flows through the gaps between the multiple fins 552, as in the cooling apparatus 52A according to the first embodiment. The heat dissipating part 55 is thus cooled, and in turn the phosphor 51 is cooled. The cooling gas having cooled the fins 552 is discharged in the −X direction via the discharge port 563 of the duct 56.

### Advantages of Third Embodiment

The projector according to the present embodiment described above provides the following advantages as well as the same advantages provided by the projector 1 according to the first embodiment.

In the wavelength converting apparatus 5C, the heat transporting part 73 is a vapor chamber. The heat transporting part 73 has the first surface 73A and the second surface 73B. The first surface 73A is a planar surface at which the heat receiver 731 is located. The second surface 73B is the surface of the heat transporting part 73 that is opposite the first surface 73A. The heat dissipating part 55 is coupled to the second surface 73B.

According to the configuration described above, the vapor chamber has high thermal diffusivity. The heat of the phosphor 51 received by the heat receiver 731 located at the first surface 73A can therefore be readily transferred to the heat dissipating part 55 coupled to the second surface 73B at the side opposite the first surface 73A. The heat of the phosphor 51 can therefore be efficiently transferred to the heat dissipating part 55, so that the efficiency at which the phosphor 51 is cooled can be increased.

Alternatively, in the wavelength converting apparatus 5C, the heat transporting part 73 is a Peltier device. In this case, the heat transporting part 73 has the planar first surface 73A, which is the heat receiver 731, and the second surface 73B opposite the first surface 73A. The heat dissipating part 55 is coupled to the second surface 73B.

According to the configuration described above, applying a voltage to the Peltier device allows the heat of the phosphor 51 received by the heat receiver 731 located at the first surface 73A to be efficiently transferred to the heat dissipating part 55 fixed to the second surface 73B at the side opposite the first surface 73A. The efficiency at which the phosphor 51 is cooled can therefore be increased.

### Fourth Embodiment

A fourth embodiment of the present disclosure will be described below.

A projector according to the present embodiment is configured in the same manner as the projector 1 according to the first embodiment, but differs therefrom in the configuration of the heat transporting part provided in the wavelength converting apparatus. In the following description, portions that are the same or substantially the same as the portions having been already described have the same reference characters and will not be described.

### Schematic Configurations of Projector and Light Source Apparatus

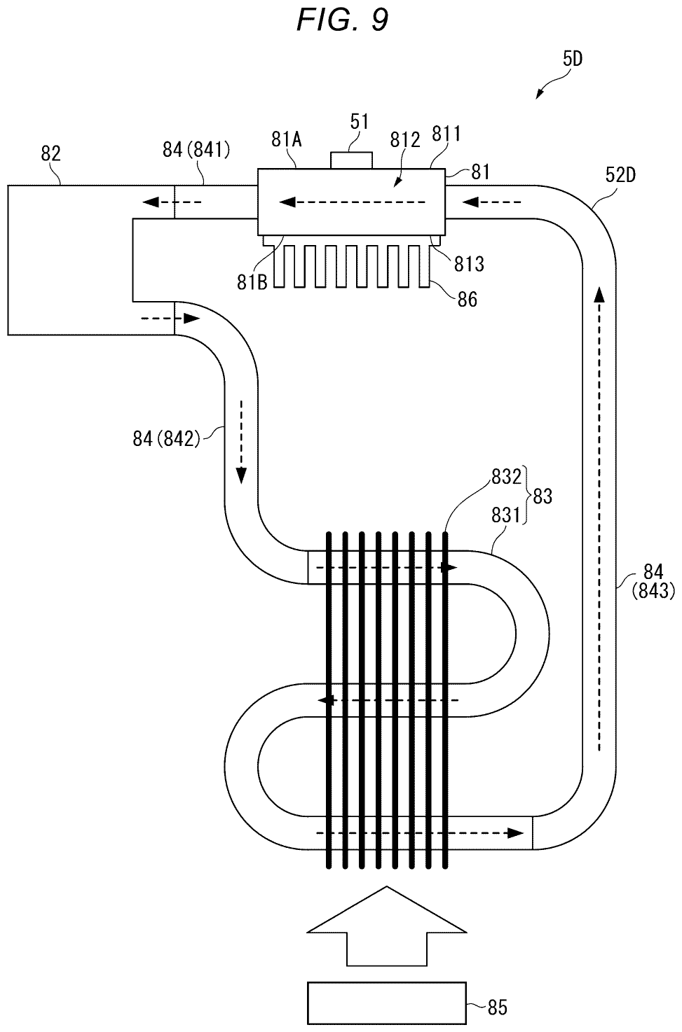

FIG. 9 is a diagrammatic view showing the configuration of a wavelength converting apparatus 5D provided in the projector according to the present embodiment.

The projector according to the present embodiment has same configurations and functions as the projector 1 according to the first embodiment except that the wavelength converting apparatus 5A is replaced with the wavelength converting apparatus 5D shown in FIG. 9. That is, the light source apparatus 4 according to the present embodiment includes wavelength converting apparatus 5D in place of the wavelength converting apparatus 5A.

### Configuration of Wavelength Converting Apparatus

The wavelength converting apparatus 5D outputs the fluorescence YL as a result of the conversion of the wavelength of the incident blue light BL in the opposite direction of the direction in which the blue light BL is incident, as the wavelength converting apparatuses 5A, 5B, and 5C according to the first to third embodiments. The wavelength converting apparatus 5D has the same configurations and functions as the wavelength converting apparatus 5A except that the cooling apparatus 52A is replaced with a cooling apparatus 52D. That is, the wavelength converting apparatus 5D includes the phosphor 51 and the cooling apparatus 52D.

### Configuration of Cooling Apparatus

The cooling apparatus 52D supports the phosphor 51 and cools the phosphor 51, as the cooling apparatus 52A, 52B, and 52C according to the first to third embodiments. The cooling apparatus 52C includes a cold plate 81, a pump 82, a radiator 83, multiple tubular parts 84, a cooling fan 85, and a heat dissipating part 86.

Out of the elements described above, the configuration of the cold plate 81 will be described later in detail.

The multiple tubular parts 84 are each configured to allow a cooling medium to flow therein. The multiple tubular parts 84 include tubular parts 841, 842, and 843.

The tubular part 841 couples the cold plate 81 and the pump 82 to each other.

The tubular part 842 couples the pump 82 and the radiator 83 to each other.

The tubular part 843 couples the radiator 83 and the cold plate 81 to each other.

The multiple tubular parts 84 link the cold plate 81, the pump 82, and the radiator 83 to each other to form an annular circulation channel of the cooling medium.

The pump 82 sends the cooling medium having flowed through the cold plate 81 to the radiator 83.

The radiator 83 cools the cooling medium flowing from the pump 82 and causes the cooled cooling medium to flow to the cold plate 81. The radiator 83 includes a heat receiving tube 831 coupled to the tubular parts 842 and 843, and multiple fins 832 provided at the heat receiving tube 831. The heat receiving tube 831 receives heat from the cooling medium flowing therein, and the multiple fins 832 dissipate the heat of the cooling medium flowing through the heat receiving tube 831 to the space outside the heat receiving tube 831. The cooling medium thus deprived of the heat and therefore cooled flows to the cold plate 81 through the tubular part 843.

The cooling fan 85 causes a cooling gas to flow to the multiple fins 832 to cool the multiple fins 832.

### Configuration of Cold Plate

The cold plate 81 is disposed in the opening 472 of the light source enclosure 47 while supporting the phosphor 51. The cold plate 81 is configured to allow the cooling medium to flow therein. The cold plate 81 includes a heat receiver 811 and heat dissipaters 812 and 813, and dissipates the heat received by the heat receiver 811 via the heat dissipaters 812 and 813 provided at positions different from the position of the heat receiver 811.

The heat receiver 811 is a planar portion that is located at a portion of the outer surface of the cold plate 81 and receives heat from a target to be cooled by the cold plate 81. In detail, the heat receiver 811 is located at a planar first surface 81A of the cold plate 81, which faces the positive end of the Z direction. The phosphor 51 is fixed to the heat receiver 811 through either solder-based metal joining or metal-based firing fixation, and the heat receiver 811 receives the heat from the phosphor 51.

Although not shown in detail, the heat dissipater 812 is configured with fins provided in the cold plate 81. Part of the heat received by the heat receiver 811 is transferred to the heat dissipater 812 via the cooling medium flowing in the cold plate 81.

Out of the outer surfaces of the cold plate 81, the heat dissipater 813 is located at a surface different from the surface at which the heat receiver 811 is located. Specifically, the heat dissipater 813 is located at a second surface 81B of the cold plate 81, which is opposite the first surface 81A, at which the heat receiver 811 is located. The heat dissipater 813 radiates the other part of the heat received by the heat receiver 811 to the heat dissipating part 86 disposed at the heat dissipater 813.

Note that the heat dissipating part 86 can be configured with a heat sink having multiple fins.

### Dissipation of Heat of Phosphor

Part of the heat of the phosphor 51 received by the heat receiver 811 of the cold plate 81 is transferred by the heat dissipater 812 to the cooling medium flowing through the cold plate 81. The cooling medium to which the heat of the phosphor 51 has been transferred flows to the radiator 83 via the pump 82, and the heat of the cooling medium having flowed to the radiator 83 is dissipated via the fins 832 of the radiator 83. The cooling medium having passed through the radiator 83 and having therefore been cooled flows again to the cold plate 81.

The other part of the heat of the phosphor 51 received by the heat receiver 811 of the cold plate 81 is dissipated by the heat dissipater 813 to the heat dissipating part 86, and the heat dissipating part 86 dissipates the transferred heat.

The heat of the phosphor 51 is thus dissipated, so that the phosphor 51 is cooled. The flow direction of the cooling medium may be the opposite direction of the direction described above in the circulation channel of the cooling apparatus 52D.

### Advantages of Fourth Embodiment

The projector according to the present embodiment described above provides the following advantages as well as the same advantages provided by the projector 1 according to the first embodiment.

In the wavelength converting apparatus 5D, the cooling apparatus 52D includes the cold plate 81, through which the cooling medium flows. The cold plate 81 has the planar first surface 81A, at which the heat receiver 811 is located. The heat receiver 811 receives the heat from the phosphor 51 fixed to the heat receiver 811.

According to the configuration described above, the heat of the phosphor 51 received by the heat receiver 811 can be dissipated by the cold plate 81 to the cooling medium flowing through the cold plate 81. The efficiency at which the phosphor 51 is cooled can therefore be increased.

The wavelength converting apparatus 5D includes the heat dissipating part 86 fixed to a surface of the cold plate 81 that differs from the first surface 81A.

According to the configuration described above, the heat transferred to the cold plate 81 can be dissipated by the heat dissipating part 86 to the space around the cold plate 81. The heat of the phosphor 51 can therefore be dissipated by the cold plate 81 to not only the cooling medium but also the gas around the cold plate 81. The efficiency at which the phosphor 51 is cooled can therefore be increased.

### Fifth Embodiment

A fifth embodiment of the present disclosure will next be described.

A projector according to the present embodiment is configured in the same manner as the projector 1 according to the first embodiment, but differs therefrom in that neither the heat transporting part 53 nor the support part 54 is provided, and that the phosphor 51 is directly fixed to the heat dissipating part 55. In the following description, portions that are the same or substantially the same as the portions having been already described have the same reference characters and will not be described.

### Schematic Configurations of Projector and Light Source Apparatus

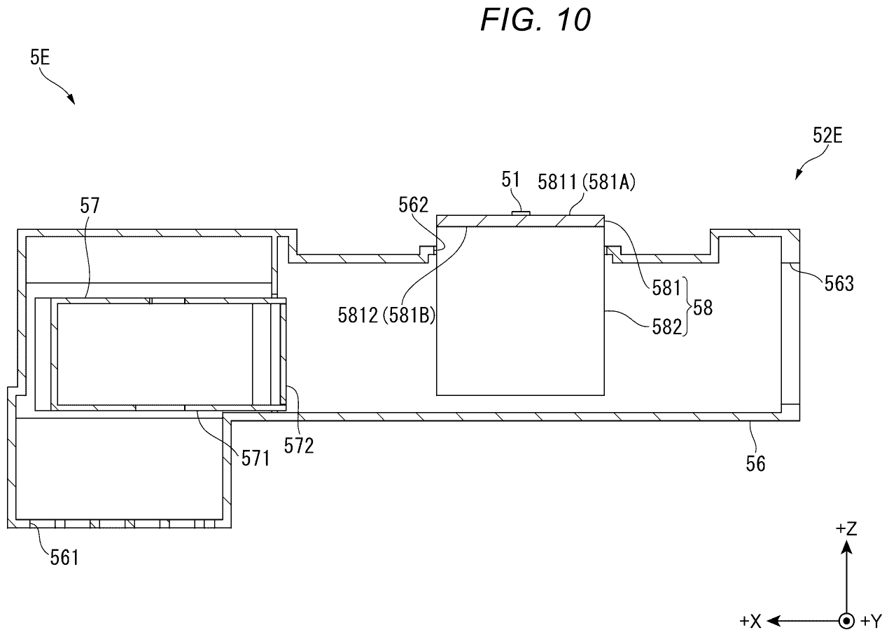

FIG. 10 is a cross-sectional view of a wavelength converting apparatus 5E provided in the projector according to the present embodiment and viewed in the +Y direction.

The projector according to the present embodiment has same configurations and functions as the projector 1 according to the first embodiment except that the wavelength converting apparatus 5A is replaced with the wavelength converting apparatus 5E shown in FIG. 10. That is, the light source apparatus 4 according to the present embodiment includes the wavelength converting apparatus 5E in place of the wavelength converting apparatus 5A.

### Configuration of Wavelength Converting Apparatus

The wavelength converting apparatus 5E outputs the fluorescence YL as a result of the conversion of the wavelength of the incident blue light BL in the opposite direction of the direction in which the blue light BL is incident, as the wavelength converting apparatuses 5A, 5B, 5C, and 5D according to the first to fourth embodiments. The wavelength converting apparatus 5E has the same configurations and functions as the wavelength converting apparatus 5A except that the cooling apparatus 52A is replaced with a cooling apparatus 52E. That is, the wavelength converting apparatus 5E includes the phosphor 51 and the cooling apparatus 52E.

### Configuration of Cooling Apparatus

The cooling apparatus 52E supports the phosphor 51 and cools the phosphor 51, as the cooling apparatus 52A according to the first embodiment. The cooling apparatus 52E includes the duct 56, the fan 57, and a heat dissipating part 58. In other words, the cooling apparatus 52E has the same configurations and functions as the cooling apparatus 52A except that the heat transporting part 53, the support part 54, and the heat dissipating part 55 are replaced with the heat dissipation part 58.

### Configuration of Heat Dissipating Part

The heat dissipating part 58 supports the phosphor 51 and dissipates the heat transferred from the phosphor 51 to the cooling gas flowing through the duct 56. That is, a portion of the heat dissipating part 58 that faces the positive end of the Z direction is exposed to the space in the light source enclosure 47 via the opening 472, and a portion of the heat dissipating part 58 that faces the negative end of the Z direction is exposed to the space in the duct 56 via the opening 562. The heat dissipating part 58 includes a base 581 and multiple heat dissipating fins 582.

The base 581 is formed in the shape of a substantially rectangular planar plate when viewed in the +Z direction, and is disposed and fixed in the opening 472. The base 581 has a planar first surface 581A facing the positive end of the Z direction and a planar second surface 581B facing the negative end of the Z direction, and further includes a planar heat receiver 5811 located at the first surface 581A, and a planar heat dissipater 5812 located at the second surface 581B. The first surface 581A and the second surface 581B are surfaces of the base 581 that are opposite each other.

The phosphor 51 is fixed to the first surface 581A through either solder-based metal joining or metal-based firing fixation. The heat receiver 5811 receives the heat from the phosphor 51 fixed to the first surface 581A.

The heat dissipater 5812 dissipates the heat of the phosphor 51 received by the heat receiver 5811 to the multiple heat dissipating fins 582.

The multiple heat dissipating fins 582 are provided side by side along the Y-axis at the second surface 581B, and the multiple heat dissipating fins 582 each extend in the −Z direction from the second surface 581B. Portions of the multiple heat dissipating fins 582 that face the negative end of the Z direction are disposed in the duct 56.

The multiple heat dissipating fins 582 therefore dissipate the heat of the phosphor 51 received by the heat receiver 5811 to the cooling gas caused by the fan 57 to flow through the duct 56 in the −X direction. That is, the multiple heat dissipating fins 582 dissipate the heat of the phosphor 51 transferred from the heat dissipater 5812 to the cooling gas flowing through the duct 56. The phosphor 51 is thus cooled.

### Advantages of Fifth Embodiment

The projector according to the present embodiment described above provides the following advantages as well as the same advantages provided by the projector 1 according to the first embodiment.

In the wavelength converting apparatus 5E, the cooling apparatus 52E includes the heat dissipating part 58, which dissipates the transferred heat. The heat dissipating part 58 includes the base 581 and the heat dissipating fins 582.

The base 581 has the planar first surface 581A, at which the heat receiver 5811 is located, and the second surface 581B opposite the first surface 581A. The heat dissipating fins 582 are provided at the second surface 581B.

According to the configuration described above, the heat of the phosphor 51 is received by the heat receiver 5811 located at the first surface 581A, and is dissipated by the heat dissipating fins 582 provided at the second surface 581B opposite the first surface 581A. The heat of the phosphor 51 can therefore be efficiently transferred to the heat dissipating fins 582, so that the efficiency at which the phosphor 51 is cooled can be increased.

### Variations of Embodiments

The present disclosure is not limited to the embodiments described above, and variations, improvements, and other modifications to the extent that the advantage of the present disclosure is achieved fall within the scope of the present disclosure.

It is assumed in the first, second, third, and fifth embodiments that the cooling apparatuses 52A, 52B, 52C, and 52E each include the duct 56 or 66, which houses any of the heat dissipating parts 55, 58, and 65, but not necessarily. The cooling apparatuses 52A, 52B, 52C, and 52E may not each include the duct 56 or 66. It is further assumed that the cooling apparatuses 52A, 52B, 52C, and 52E each include the fan 57, which causes the cooling gas to flow through the duct 56 or 66, but not necessarily. The fan 57 may be omitted, and a cooling gas that cools other cooling targets may flow to the heat dissipating part 55, 58, or 65.

In the embodiments described above, the projector includes the three light modulators 343B, 343G, and 343R, but not necessarily. The present disclosure is also applicable to a projector including two or fewer, or four or larger number of light modulators.

In the embodiments described above, the image projecting apparatus 3 is formed in a substantially L shape shown in FIG. 1, but not necessarily. For example, a configuration having a substantially U shape may be employed, and the optical parts employed in the image projecting apparatus and the layout of the optical parts can be changed as appropriate.

It is assumed in the embodiments described above that the light modulators 343 each include a transmissive liquid crystal panel having a light incident surface and a light exiting surface different from each other, but not necessarily. The light modulators may each be a reflective liquid crystal panel having a surface that serves both as the light incident surface and the light exiting surface. Furthermore, a light modulator using any element other than a liquid-crystal-based element, such as a device using micromirrors, for example, a digital micromirror device (DMD), may be employed as long as the element is capable of modulating an incident luminous flux to form an image according to image information.

The aforementioned embodiments have been described with reference to the case where a projector uses the light source apparatus 4 including any of the wavelength converting apparatuses 5A, 5B, 5C, 5D, and 5E, but not necessarily. The light source apparatus according to the present disclosure may be used for a lighting instrument, a headlight of an automobile, or the like.

### Summary of Present Disclosure

The present disclosure will be summarized below in the form of additional remarks.

### Additional Remark 1

A wavelength converting apparatus including:
a phosphor that is a heat source and is configured to emit light having a specific wavelength band; and
a cooling apparatus that includes a planar heat receiver at which the phosphor is disposed, and is configured to dissipate heat of the phosphor received by the heat receiver.

According to the configuration described above, the cooling apparatus, which receives the heat generated by the phosphor via the heat receiver and dissipates the received heat, can cool the phosphor. In the thus configured cooling apparatus, the heat receiver is formed in a planar shape, so that the area where the heat receiver and the phosphor are in contact with each other can be increased, and the phosphor is disposed at the heat receiver, so that the heat can be efficiently transferred from the phosphor to the heat receiver. The phosphor can therefore be effectively cooled.

### Additional Remark 2

The wavelength converting apparatus according to the additional remark 1, wherein
the cooling apparatus includes
a heat dissipating part configured to dissipate transferred heat, and
a heat transporting part configured to evaporate a working fluid in a liquid phase by using the heat received by the heat receiver to change the working fluid in the liquid phase to the working fluid in a gaseous phase, and dissipate heat of the working fluid in the gaseous phase to the heat dissipating part to change the working fluid in the gaseous phase to the working fluid in the liquid phase, and
the heat receiver is provided at the heat transporting part.

According to the configuration described above, the working fluid having changed from the liquid phase to the gaseous phase due to the heat received by the heat receiver changes from the gaseous phase to the liquid phase by transferring the heat to the heat dissipating part. The heat received by the heat receiver can therefore be quickly transferred to the heat dissipating part via the working fluid. The heat of the phosphor can therefore be quickly transferred to the heat dissipating part, so that the efficiency at which the phosphor is cooled can be increased.

### Additional Remark 3

The wavelength converting apparatus according to the additional remark 2, further including
a support part having a groove in which the heat transporting part is disposed,
wherein the heat transporting part is a heat pipe.

According to the configuration described above, the heat transporting part, which is a heat pipe, is disposed in the groove of the support part, so that the heat transporting part can be disposed in a stable manner.

### Additional Remark 4

The wavelength converting apparatus according to the additional remark 3, wherein
the support part is configured to receive the heat from the heat transporting part, and
the heat dissipating part is coupled to the support part.

According to the configuration described above, the heat can be transferred from the heat transporting part disposed in the groove to the support part, so that the support part can be used as another heat dissipating part. Furthermore, since the heat dissipating part and the support part are coupled to each other, the heat transferred to the support part can be transferred to the heat dissipating part. The number of heat transporting paths from the phosphor to the heat dissipating part can therefore be increased, so that the efficiency at which the heat is transferred from the phosphor to the heat dissipating part can be increased, and the efficiency at which the phosphor is cooled can hence be increased.

### Additional Remark 5

The wavelength converting apparatus according to the additional remark 3 or 4, wherein
the heat dissipating part is provided at each of opposite ends of the heat pipe.

According to the configuration described above, the heat dissipation area of the phosphor can be increased. Furthermore, the distance between the heat receiver and the heat dissipating part can be shortened as compared with the case where the heat receiver is provided at one end of the heat pipe and the heat dissipating part is provided at the other end of the heat pipe, so that the heat of the phosphor can be transferred to the heat dissipating part quickly and efficiently. The efficiency at which the phosphor is cooled can therefore be increased.

### Additional Remark 6

The wavelength converting apparatus according to the additional remark 2, wherein
the heat transporting part is a vapor chamber,
the vapor chamber has
a planar first surface at which the heat receiver is located, and
a second surface opposite the first surface, and
the heat dissipating part is coupled to the second surface.

According to the configuration described above, the vapor chamber has high thermal diffusivity. The heat of the phosphor received by the heat receiver located at the first surface can therefore be readily transferred to the heat dissipating part coupled to the second surface at the side opposite the first surface. The heat of the phosphor can therefore be efficiently transferred to the heat dissipating part, so that the efficiency at which the phosphor is cooled can be increased.

### Additional Remark 7

The wavelength converting apparatus according to the additional remark 1, wherein
the cooling apparatus includes
a Peltier device having a planar first surface that is the heat receiver, and a second surface opposite the first surface, and
a heat dissipating part coupled to the second surface.

According to the configuration described above, applying a voltage to the Peltier device allows the heat of the phosphor received by the heat receiver, which is the first surface, to be efficiently transferred to the heat dissipating part fixed to the second surface at the side opposite the first surface. The efficiency at which the phosphor is cooled can therefore be increased.

### Additional Remark 8

The wavelength converting apparatus according to the additional remark 1, wherein
the cooling apparatus includes a cold plate which has a planar first surface at which the heat receiver is located, and through which a cooling medium flows.

According to the configuration described above, the heat of the phosphor received by the heat receiver can be dissipated by the cold plate to the cooling medium flowing through the cold plate. The efficiency at which the phosphor is cooled can therefore be increased.

### Additional Remark 9

The wavelength converting apparatus according to the additional remark 8, further including
a heat dissipating part fixed to a surface of the cold plate that differs from the first surface.

According to the configuration described above, the heat transferred to the cold plate can be dissipated by the heat dissipating part to the space around the cold plate. The heat of the phosphor can therefore be dissipated by the cold plate to not only the cooling medium but also the gas around the cold plate. The efficiency at which the phosphor is cooled can therefore be increased.

### Additional Remark 10

The wavelength converting apparatus according to the additional remark 1, wherein
the cooling apparatus includes a heat dissipating part configured to dissipate transferred heat, and
the heat dissipating part includes
a base having a planar first surface at which the heat receiver is located, and a second surface opposite the first surface, and
a heat dissipating fin provided at the second surface.

According to the configuration described above, the heat of the phosphor is received by the first surface, which is the heat receiver, and is dissipated by the heat dissipating fin provided at the second surface opposite the first surface. The heat of the phosphor can therefore be efficiently transferred to the heat dissipating fin, so that the efficiency at which the phosphor is cooled can be increased.

### Additional Remark 11

The wavelength converting apparatus according to any one of the additional remarks 2 to 7, 9, and 10, further comprising:
a duct in which the heat dissipating part is disposed and through which a cooling gas is allowed to flow; and
a fan configured to cause the cooling gas to flow through the duct.

According to the configuration described above, in which the heat dissipating part is disposed in the duct, through which the cooling gas is caused to flow by the fan, the heat dissipating part, to which the heat of the phosphor is transferred, can be effectively cooled, and in turn the efficiency at which the phosphor is cooled can be increased.

### Additional Remark 12

The wavelength converting apparatus according to any one of the additional remarks 1 to 11, wherein the phosphor is fixed to the heat receiver through either solder-based metal joining or metal-based firing fixation.

According to the configuration described above, the thermal resistance between the phosphor and the heat receiver can be reduced, so that the heat can be satisfactorily transferred from the phosphor to the heat receiver. The efficiency at which the phosphor is cooled can therefore be increased.

### Additional Remark 13

A light source apparatus including:
the wavelength converting apparatus according to any one of the additional remarks 1 to 12; and
a light source configured to output light that enters the phosphor.

The configuration described above can provide the same effects as those provided by the wavelength converting apparatus described above. The amount of light that enters the wavelength converting apparatus can therefore be increased, so that the light source apparatus can output high-luminance light.

### Additional Remark 14

A projector including:
the light source apparatus according to the additional remark 13;
a light modulator configured to modulate light from the light source apparatus; and
a projection optical apparatus configured to project the light modulated by the light modulator.

According to the configuration described above, the same advantages as those provided by the light source apparatus described above can be provided, so that the projector can project high-luminance image light.

What is claimed is:

1. A wavelength converting apparatus comprising:
a phosphor that is a heat source and is configured to emit light having a specific wavelength band; and
a cooling apparatus that includes a planar heat receiver at which the phosphor is disposed, and is configured to dissipate heat of the phosphor received by the heat receiver.

2. The wavelength converting apparatus according to claim 1, wherein
the cooling apparatus includes
a heat dissipating part configured to dissipate transferred heat, and
a heat transporting part configured to evaporate a working fluid in a liquid phase by using the heat received by the heat receiver to change the working fluid in the liquid phase to the working fluid in a gaseous phase, and dissipate heat of the working fluid in the gaseous phase to the heat dissipating part to change the working fluid in the gaseous phase to the working fluid in the liquid phase, and
the heat receiver is provided at the heat transporting part.

3. The wavelength converting apparatus according to claim 2, further comprising
a support part having a groove in which the heat transporting part is disposed,
wherein the heat transporting part is a heat pipe.

4. The wavelength converting apparatus according to claim 3, wherein
the support part is configured to receive the heat from the heat transporting part, and
the heat dissipating part is coupled to the support part.

5. The wavelength converting apparatus according to claim 3, wherein
the heat dissipating part is provided at each of opposite ends of the heat pipe.

6. The wavelength converting apparatus according to claim 2, wherein
the heat transporting part is a vapor chamber,
the vapor chamber has
a planar first surface at which the heat receiver is located, and
a second surface opposite the first surface, and
the heat dissipating part is coupled to the second surface.

7. The wavelength converting apparatus according to claim 1, wherein
the cooling apparatus includes
a Peltier device having a planar first surface that is the heat receiver, and a second surface opposite the first surface, and
a heat dissipating part coupled to the second surface.

8. The wavelength converting apparatus according to claim 1, wherein
the cooling apparatus includes a cold plate which has a planar first surface at which the heat receiver is located, and through which a cooling medium flows.

9. The wavelength converting apparatus according to claim 8, further comprising
a heat dissipating part fixed to a surface of the cold plate that differs from the first surface.

10. The wavelength converting apparatus according to claim 1, wherein
the cooling apparatus includes a heat dissipating part configured to dissipate transferred heat, and
the heat dissipating part includes
a base having a planar first surface at which the heat receiver is located, and a second surface opposite the first surface, and
a heat dissipating fin provided at the second surface.

11. The wavelength converting apparatus according to claim 2, further comprising:
a duct in which the heat dissipating part is disposed and through which a cooling gas is allowed to flow; and
a fan configured to cause the cooling gas to flow through the duct.

12. The wavelength converting apparatus according to claim 1, wherein
the phosphor is fixed to the heat receiver through either solder-based metal joining or metal-based firing fixation.

13. A light source apparatus comprising:
the wavelength converting apparatus according to claim 1; and
a light source configured to output light that enters the phosphor.

14. A projector comprising:
the light source apparatus according to claim 13;
a light modulator configured to modulate light from the light source apparatus; and
a projection optical apparatus configured to project the light modulated by the light modulator.
